(19) United States
(12) Patent Application Publication
(10) Pub. No.: US 2012/0062091 A1
(43) Pub. Date: Mar. 15, 2012

(54) VERTICAL MOUNTING RAIL WITH CABLE MANAGEMENT FEATURES

(76) Inventors: D. Brian DONOWHO, Austin, TX (US); William Drew Krietzman, Denver, CO (US); Brandi May Oldt, Austin, TX (US)

(21) Appl. No.: 13/229,708

(22) Filed: Sep. 10, 2011

Related U.S. Application Data
(60) Provisional application No. 61/381,918, filed on Sep. 10, 2010.

(51) Int. Cl. H05K 7/18; F16L 3/08

(52) U.S. Cl. 312/351.1

(57) ABSTRACT

An electronic equipment enclosure includes a frame structure that includes side cross members between front and rear frames, a vertical mounting rail fastened to the frame structure, and a first cable management structure. The vertical mounting rail includes a fastening portion, for interfacing with the frame structure, and at least one support portion including an aperture therein. The first cable management structure has a boss adapted to be maneuvered into the aperture and seated therein so as to fasten the first cable management structure to the at least one support portion without a separate fastener.

### CROSS-REFERENCE TO RELATED APPLICATION

The present application is a U.S. non-provisional patent application of, and claims priority under 35 U.S.C. §119(e) to, U.S. provisional patent application Ser. No. 61/381,918, filed Sep. 10, 2010, which '918 application is incorporated by reference herein in its entirety. Additionally, each of the following U.S. patent applications, and any application publication thereof, is expressly incorporated by reference herein in its entirety:

(a) U.S. provisional patent application Ser. No. 61/381,904, filed Sep. 10, 2010, and entitled, “ELECTRONIC EQUIPMENT CABINET STRUCTURE;”

(b) U.S. provisional patent application Ser. No. 61/381,905, filed Sep. 10, 2010, and entitled, “CABLE PASS-THROUGH PANEL FOR ELECTRONIC EQUIPMENT ENCLOSURE;”

(c) U.S. provisional patent application Ser. No. 61/381,909, filed Sep. 10, 2010, and entitled, “RAIL SEAL FOR ELECTRONIC EQUIPMENT ENCLOSURE;”

(d) U.S. provisional patent application Ser. No. 61/381,912, filed Sep. 10, 2010, and entitled, “RAIL MOUNTING CLAMP FOR ELECTRONIC EQUIPMENT ENCLOSURE;”

(e) U.S. non-provisional patent application Ser. No. 13/229,704, filed Sep. 10, 2011, and entitled, “ELECTRONIC EQUIPMENT CABINET STRUCTURE;”

(f) U.S. non-provisional patent application Ser. No. 13/229,705, filed Sep. 10, 2011, and entitled, “CABLE PASS-THROUGH PANEL FOR ELECTRONIC EQUIPMENT ENCLOSURE;”

(g) U.S. non-provisional patent application Ser. No. 13/229,706, filed Sep. 10, 2011, and entitled, “RAIL SEAL FOR ELECTRONIC EQUIPMENT ENCLOSURE;” and

(h) U.S. non-provisional patent application Ser. No. 13/229,707, filed Sep. 10, 2011, and entitled, “RAIL MOUNTING CLAMP FOR ELECTRONIC EQUIPMENT ENCLOSURE.”

### COPYRIGHT STATEMENT

All of the material in this patent document is subject to copyright protection under the copyright laws of the United States and other countries. The copyright owner has no objection to the facsimile reproduction by anyone of the patent document or the patent disclosure, as it appears in official governmental records but, otherwise, all other copyright rights whatsoever are reserved.

### BACKGROUND OF THE PRESENT INVENTION

1. Field of the Present Invention

The present invention relates generally to the field of racks, frames and cabinets for mounting and storing electronic components, and, more particularly, to reduced-complexity structures with high strength and capacity.

2. Background

Racks, frames and cabinets for mounting and storing electronic components have been well known for many years. Frames and racks are typically simple rectangular frameworks on which electronic components may be mounted, or on which other mounting members, such as shelves or brackets, may be mounted which in turn may support the electronic components. Cabinets are typically frames on which panels or doors, or both, are hung to provide aesthetic improvement, to protect the components from external influences, to provide security for the components stored inside, or for other reasons. Racks, frames and cabinets (sometimes collectively referred to hereinafter as “enclosures”) have been built in many different sizes and with many different proportions in order to best accommodate the components which they are designed to store.

Various aspects of these enclosures have increased part counts and weight and created additional cost and manufacturing complications. In one example, cable management accessories and equipment are mounted in an enclosure on a bracket that is attached to a vertically-oriented equipment mounting rail. Because the bracket is a separate structural component from the vertical mounting rail, these structures occupy greater space within the enclosure. Additionally, such structures typically result in greater cost due to the extra materials and hardware components necessary to install the separate bracket.

Accordingly, a need exists for improved design and manufacturability in racks, frames and cabinets in order to enhance the utilization of space within an enclosure and reduce manufacturing and assembly costs.

### SUMMARY OF THE PRESENT INVENTION

The present invention includes many aspects and features. Moreover, while many aspects and features relate to, and are described in, the context of enclosures for electronic equipment, the present invention is not limited to use only in enclosures for electronic equipment, as will become apparent from the following summaries and detailed descriptions of aspects, features, and one or more embodiments of the present invention.

Broadly defined, the present invention according to a first aspect includes an electronic equipment enclosure having a frame structure that includes side cross members between front and rear frames, a vertical mounting rail fastened to the frame structure, and one or more cable management structures. The vertical mounting rail includes a fastening surface, for interfacing with the frame structure, and first, second and third support surfaces located successively adjacent one another and away from the fastening surface. One or more cable management structures are mounted to at least one of the first or second support surfaces.

In features of this aspect, the first, second and third support surfaces may be arranged at right angles relative to one another; and the second support surface may have a width greater than that of the first or third support surfaces.

In further features of this aspect, the third support surface may be an equipment mounting rail; and the equipment mounting rail may include a plurality of apertures extending therethrough for mounting cable management equipment thereto.

In still further features of this aspect, the one or more cable management structures may include at least one D-ring; the at least one D-ring may be mounted on the first support surface; and the first support surface may include a plurality of keyhole apertures for accommodating corresponding keyhole bosses of the at least one D-ring.

In still further features of this aspect, the one or more cable management structures may include at least one multi-fingered cable guide; and the at least one multi-fingered cable guide may be mounted on the second support surface.

In another feature of this aspect, the one or more cable management structures may include at least one D-ring mounted on the first support surface and at least one multi-fingered cable guide mounted on the second support surface.

Broadly defined, the present invention according to a second aspect includes an electronic equipment enclosure substantially as shown and described.

Broadly defined, the present invention according to a third aspect includes a vertical mounting rail for fastening in an electronic equipment enclosure. The vertical mounting rail includes a fastening surface, for interfacing with a frame structure, and first, second and third support surfaces located successively adjacent one another and away from the fastening surface. One or more cable management structures are mountable to at least one of the first or second support surfaces.

In features of this aspect, the first, second and third support surfaces may be arranged at right angles relative to one another; and the second support surface may have a width greater than that of the first or third support surfaces.

In further features of this aspect, the third support surface may be an equipment mounting rail; and the equipment mounting rail may include a plurality of apertures extending therethrough for mounting cable management equipment thereto.

In still further features of this aspect, the one or more cable management structures may include at least one D-ring; the at least one D-ring may be mountable on the first support surface; and the first support surface may include a plurality of keyhole apertures for accommodating corresponding keyhole bosses of the at least one D-ring.

In still further features of this aspect, the one or more cable management structures may include at least one multi-fingered cable guide; and the at least one multi-fingered cable guide may be mountable on the second support surface.

In another feature of this aspect, the one or more cable management structures may include at least one D-ring mountable on the first support surface and at least one multi-fingered cable guide mountable on the second support surface.

Broadly defined, the present invention according to a fourth aspect includes a vertical mounting rail, for fastening in an electronic equipment enclosure, as substantially shown and described.

Broadly defined, the present invention according to a fifth aspect includes a method of accomplishing cable management in an electronic equipment enclosure, substantially as shown and described.

Broadly defined, the present invention according to a sixth aspect includes an electronic equipment enclosure that includes a frame structure that includes side cross members between front and rear frames, a vertical mounting rail fastened to the frame structure, and a first cable management structure. The vertical mounting rail includes a fastening portion, for interfacing with the frame structure, and at least one support portion including an aperture therein. The first cable management structure has a boss adapted to be maneuvered into the aperture and seated therein so as to fasten, without a separate fastener, the first cable management structure to the at least one support portion.

In features of this aspect, the first cable management structure may be adapted to be snap-fit to the at least one support portion; and the first cable management structure may be adapted to be fastened to the at least one support portion without the aid of tools.

In further features of this aspect, a second cable management structure having a boss may be adapted to be maneuvered into another aperture of the at least one support portion, and seated therein, so as to fasten, without a separate fastener, the second cable management structure to the at least one support portion; the second cable management structure may be of the same type as that of the first cable management structure; and the second cable management structure may be of a different type than that of the first cable management structure.

In further features of this aspect, the aperture of the at least one support portion may have a keyhole shape; and the at least one support portion may be an equipment mounting rail.

In further features of this aspect, the at least one support portion may include first, second and third support portions located successively adjacent one another; the first, second and third support portions may be arranged at right angles relative to one another; the second support portion may have a width greater than that of the first or third support portions; a second cable management structure may be fastened to the same support portion as that of the first cable management structure; and a second cable management structure may be fastened to a different support portion than that of the first cable management structure.

In still further features of this aspect, the first cable management structure may be a D-ring; the first cable management structure may be a multi-fingered cable guide; the first cable management structure may be a T-channel cable manager array; the first cable management structure may be a cable manager spool; and the first cable management structure may be a vertical C-channel cable manager.

Broadly defined, the present invention according to a seventh aspect includes a vertical mounting rail for fastening in an electronic equipment enclosure. The vertical mounting rail includes a fastening portion for interfacing with a frame structure and at least one support portion including an aperture therein adapted to receive and seat a boss of a first cable management structure, thereby fastening the first cable management structure to the at least one support portion without a separate fastener.

In features of this aspect, the at least one support portion may be adapted to permit the first cable management structure to be snap-fitted thereto; and the at least one support portion may be adapted to permit the first cable management structure to be fastened thereto without the aid of tools.

In further features of this aspect, the at least one support portion may include another aperture therein adapted to receive and seat the boss of a second cable management structure, thereby fastening the second cable management structure to the at least one support portion without a separate fastener; the second cable management structure may be of the same type as that of the first cable management structure; and the second cable management structure may be of a different type than that of the first cable management structure.

In further features of this aspect, the aperture of the at least one support portion may have a keyhole shape; and the at least one support portion may be an equipment mounting rail.

In further features of this aspect, the at least one support portion may include first, second and third support portions located successively adjacent one another; the first, second and third support portions may be arranged at right angles relative to one another; the second support portion may have a width greater than that of the first or third support portions; and any of the first, second and third support portions may be adapted to support the first cable management structure.

In still further features of this aspect, the first cable management structure may be a D-ring; the first cable management structure may be a multi-fingered cable guide; the first cable management structure may be a T-channel cable manager array; the first cable management structure may be a cable manager spool; and the first cable management structure may be a vertical C-channel cable manager.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Further features, embodiments, and advantages of the present invention will become apparent from the following detailed description with reference to the drawings, wherein:

FIG. 1 is a front isometric view of an electronic equipment enclosure frame in accordance with one or more preferred embodiments of the present invention, shown with a pair of vertical mounting rails installed thereon;

FIG. 2 is an isometric view of a frame structure of similar construction to that of FIG. 1, but of greater depth, shown with panels installed thereon;

FIG. 3 is an isometric view of one of the vertical mounting rails of FIG. 1, and

FIG. 4 is a top cross-sectional view of a portion of the frame structure of FIG. 1, taken along line 4-4, showing the connection of one of the mounting rails to one of the side cross members;

FIG. 5 is an isometric view of the frame structure of FIG. 1, shown with a plurality of D-rings mounted on each vertical mounting rail;

FIG. 6 is an enlarged fragmentary isometric view of the top right corner of the frame structure of FIG. 5;

FIG. 7 is an enlarged fragmentary orthogonal view of one of the D-rings of FIG. 5 shown detached from the vertical mounting rail;

FIG. 8 is an isometric view of a frame structure of similar construction to that of FIG. 1, but of greater depth and width, shown with an alternative type of vertical mounting rail installed thereon;

FIG. 9 is an isometric view of one of the vertical mounting rails of FIG. 8;

FIG. 10 is an enlarged fragmentary isometric view of the top left corner of the frame structure of FIG. 8;

FIGS. 11 and 12 are enlarged fragmentary orthogonal views of the left side and rear of one of the D-rings of FIG. 8 shown detached from the vertical mounting rail;

FIG. 13 is a fragmentary isometric view of a top portion of the vertical mounting rail of FIG. 3, shown with a plurality of cable management structures in the form of multi-fingered cable guides mounted thereon;

FIG. 14 is an exploded fragmentary isometric view of the vertical mounting rail and cable guides of FIG. 13;

FIG. 15 is a fragmentary isometric view of a top portion of the vertical mounting rail of FIG. 9, taken from the left side, shown with a plurality of cable management structures in the form of multi-fingered cable guides, doors and door supports mounted thereon;

FIG. 16A is a partially exploded fragmentary isometric view, taken from the right side, of the arrangement of FIG. 15;

FIG. 16B is a partially exploded fragmentary isometric view, taken from the right side, of an alternative embodiment of the arrangement of FIG. 16A;

FIG. 17 is an isometric view of the frame structure of FIG. 1, shown with a T-channel cable manager array mounted on one of the vertical mounting rails;

FIG. 18 is an isometric view of the frame structure of FIG. 1, shown with a plurality of cable manager spools mounted on one of the vertical mounting rails;

FIG. 19 is an isometric view of the frame structure of FIG. 1, shown with a plurality of vertical C-channel cable managers mounted on one of the vertical mounting rails; and

FIG. 20 is an isometric view of the frame structure of FIG. 1, shown with a multi-finger cable manager array mounted on one of the vertical mounting rails.

### DETAILED DESCRIPTION

As a preliminary matter, it will readily be understood by one having ordinary skill in the relevant art (“Ordinary Artisan”) that the present invention has broad utility and application. Furthermore, any embodiment discussed and identified as being “preferred” is considered to be part of a best mode contemplated for carrying out the present invention. Other embodiments also may be discussed for additional illustrative purposes in providing a full and enabling disclosure of the present invention. As should be understood, any embodiment may incorporate only one or a plurality of the above-disclosed aspects of the invention and may further incorporate only one or a plurality of the above-disclosed features. Moreover, many embodiments, such as adaptations, variations, modifications, and equivalent arrangements, will be implicitly disclosed by the embodiments described herein and fall within the scope of the present invention.

Accordingly, while the present invention is described herein in detail in relation to one or more embodiments, it is to be understood that this disclosure is illustrative and exemplary of the present invention, and is made merely for the purposes of providing a full and enabling disclosure of the present invention. The detailed disclosure herein of one or more embodiments is not intended, nor is to be construed, to limit the scope of patent protection afforded the present invention, which scope is to be defined by the claims and the equivalents thereof. It is not intended that the scope of patent protection afforded the present invention be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection afforded the present invention is to be defined by the appended claims rather than the description set forth herein.

Additionally, it is important to note that each term used herein refers to that which the Ordinary Artisan would understand such term to mean based on the contextual use of such term herein. To the extent that the meaning of a term used herein—as understood by the Ordinary Artisan based on the contextual use of such term—differs in any way from any particular dictionary definition of such term, it is intended that the meaning of the term as understood by the Ordinary Artisan should prevail.

Regarding applicability of 35 U.S.C. §112, ¶6, no claim element is intended to be read in accordance with this statutory provision unless the explicit phrase “means for” or “step for” is actually used in such claim element, whereupon this statutory provision is intended to apply in the interpretation of such claim element.

Furthermore, it is important to note that, as used herein, “a” and “an” each generally denotes “at least one,” but does not exclude a plurality unless the contextual use dictates otherwise. Thus, reference to “a picnic basket having an apple” describes “a picnic basket having at least one apple” as well as “a picnic basket having apples.” In contrast, reference to “a picnic basket having a single apple” describes “a picnic basket having only one apple.”

When used herein to join a list of items, “or” denotes “at least one of the items,” but does not exclude a plurality of items of the list. Thus, reference to “a picnic basket having cheese or crackers” describes “a picnic basket having cheese without crackers,” “a picnic basket having crackers without cheese,” and “a picnic basket having both cheese and crackers.” Finally, when used herein to join a list of items, “and” denotes “all of the items of the list.” Thus, reference to “a picnic basket having cheese and crackers” describes “a picnic basket having cheese, wherein the picnic basket further has crackers,” as well as describes “a picnic basket having crackers, wherein the picnic basket further has cheese.”

Referring now to the drawings, in which like numerals represent like components throughout the several views, one or more preferred embodiments of the present invention are next described. The following description of one or more preferred embodiments is merely exemplary in nature and is in no way intended to limit the invention, its implementations, or uses.

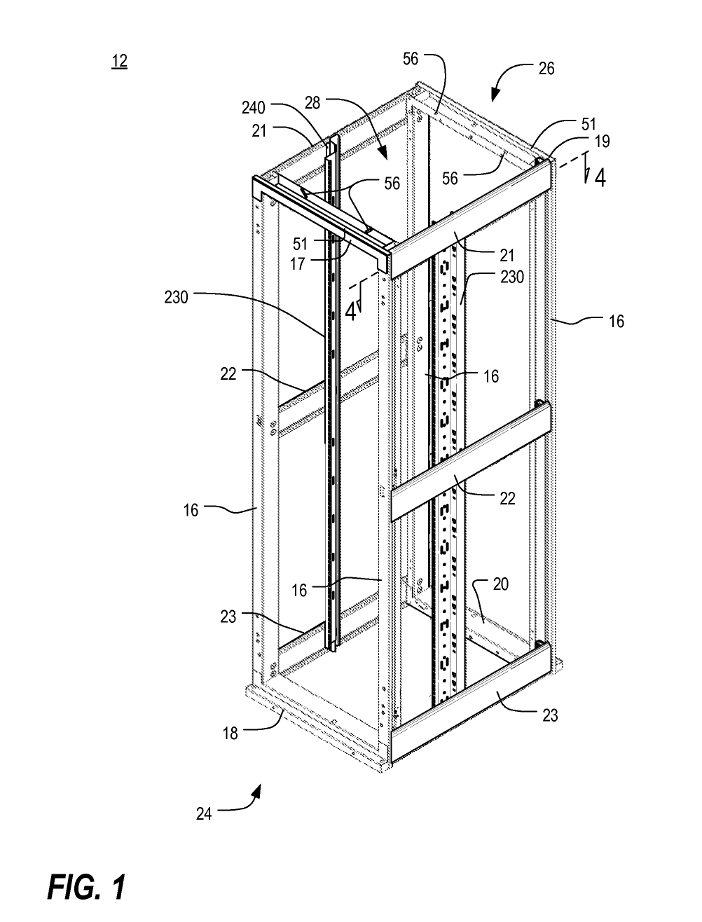

FIG. 1 is a front isometric view of an electronic equipment enclosure frame 12 in accordance with one or more preferred embodiments of the present invention, shown with a pair of vertical mounting rails 230 installed thereon. As shown therein, the frame structure 12 includes four vertical support posts 16, upper and lower front cross members 17,18, upper and lower rear cross members 19,20 and three pairs of side cross members 21,22,23. Each vertical support post 16 includes a plurality of cross member attachment apertures at each end. Two of the vertical support posts 16 are connected together at their upper and lower ends by the upper and lower front cross members 17,18, respectively, and the other two support posts 16 are connected together at their upper and lower ends by the upper and lower rear cross members 19,20, respectively. The front cross members 17,18 and their respective support posts 16 thus define a front frame (sometimes referred to as a door threshold frame) 24, and the rear cross members 19,20 and their respective support posts 16 define a rear door threshold frame 26. The front and rear frames 24,26 may then be connected together at their respective corners by the upper, middle and lower side cross members 21,22,23.

Although not specifically identified in FIG. 1, each upper and lower cross member 17,19 and 18,20 includes a plurality of tabs or gussets, adapted to interact with a respective end of a vertical support post 16, extending therefrom, and these tabs may be plug welded to the vertical support posts 16. Such an arrangement may be disclosed, for example, in co-pending, commonly-assigned non-provisional patent application Ser. No. 13/229,704, entitled, “ELECTRONIC EQUIPMENT CABINET STRUCTURE” (the “'704 Application”). Furthermore, the lower corners of each frame 24,26 may be reinforced and supported by caster plates which in turn are supported by casters. Such an arrangement may also be disclosed, for example, in the '704 Application.

Although the particular frame structure 12 described and illustrated herein includes various novel aspects, it will be apparent to the Ordinary Artisan that some aspects of the present invention are likewise applicable to frame structures having one or more elements of generally conventional design and construction. Furthermore, in some embodiments, other frame elements may be used, other connection means may be used to join the various members together, or both. In this regard, other examples of conventional connection means are described in commonly-assigned U.S. Pat. No. 6,185,098, U.S. Pat. No. 7,119,282, U.S. Pat. No. 7,697,285, U.S. Patent Application Publication No. US 2009/0190307 A1, U.S. Patent Application Publication No. US 2009/0227197 A1, U.S. Patent Application Publication No. US 2009/0283488 A1, and U.S. Patent Application Publication No. US 2010/0172092 A1, the entirety of each of which is incorporated herein by reference. Although likewise not illustrated herein, the precision and the stability of each of the corners of at least some types of four post frame structures may be enhanced by utilizing a self-squaring corner attachment bracket such as that disclosed by commonly-assigned U.S. Pat. No. 5,997,117, entitled “RACK FRAME CABINET,” the entirety of which is hereby incorporated by reference.

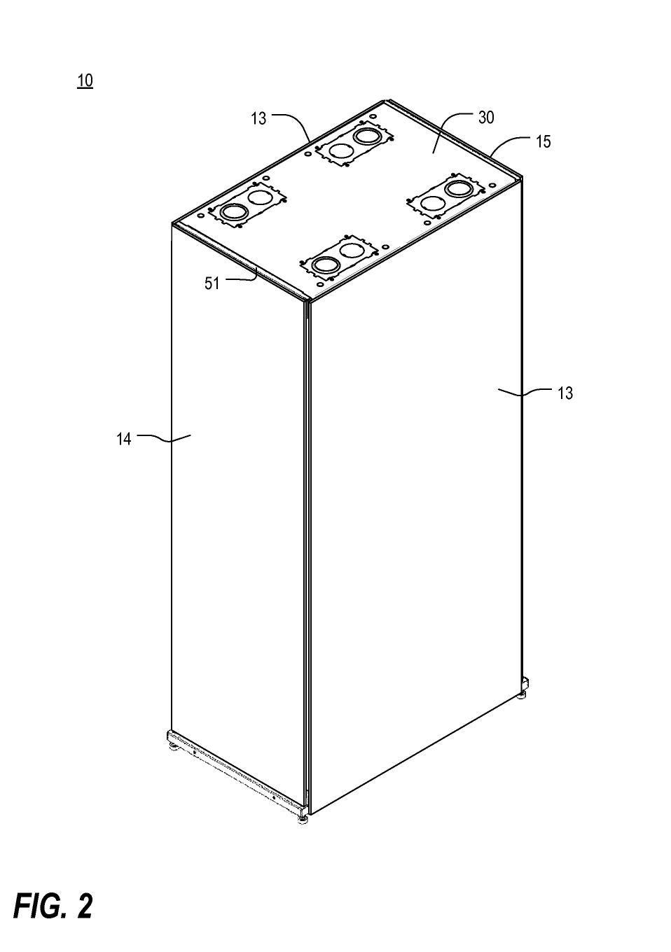

The frame structure 12 may be enclosed by one or more panels to form an electronic equipment enclosure 10. FIG. 2 is an isometric view of a frame structure 12 of similar construction to that of FIG. 1, but of greater depth, shown with panels installed thereon. As shown therein, the enclosure 10 may include right and/or left panels 13, a front panel 14, and a rear panel 15, one or more of which may be configured to operate as a door to the interior of the enclosure 10 (not illustrated). Various different connection means may be used to join the various panels 13,14,15 to the frame structure 12. One or more novel connection means may be described and/or illustrated herein. However, although not illustrated herein, it will be apparent to the Ordinary Artisan that in at least some embodiments, any of a variety of other connection means may be used instead to join the panels to the frame structure 12.

The enclosure 10 further includes a generally flat top panel 30 sized and shaped to fit an opening 28 defined by the four vertical support posts 16 in connection with the upper front cross member 17, the upper rear cross member 19, and the upper side cross members 21. When installed, the top panel 30 covers the opening 28. In a contemplated embodiment, the top panel 30 is manufactured from sheet metal or other metal-based material. The top panel 30 may include features such as those described in co-pending, commonly-assigned non-provisional patent application Ser. No. 13/229,705, entitled, “CABLE PASS-THROUGH PANEL FOR ELECTRONIC EQUIPMENT ENCLOSURE” (the “'705 Application”).

In a contemplated embodiment, the upper front and rear cross members 17,19 each include two spring pins 56 and a retaining flange 51 as seen, for example, in FIG. 1. As described in the '705 Application, the spring pins 56 and end flanges 51 may be utilized to facilitate reversible, tool-free installation of the top panel 30.

As shown in FIG. 1, the frame structure 12 further includes one or more vertical mounting rails 230 that extend therein in a generally vertical orientation. Each vertical mounting rail 230 typically has a series of holes 232 formed therein to facilitate easy mounting of a wide variety of equipment to the frame structure 12. As will be explained in greater detail, one or more mounting clamps 240 may be used to facilitate attachment of the vertical mounting rail 230 to the frame structure 12. Other examples of frame structures with vertical mounting rails are described in commonly-assigned U.S. Pat. No. 5,997,117, U.S. Pat. No. 7,839,635, U.S. Pat. No. 7,804,685, U.S. Patent Application Publication No. US 2009/0227197 A1, and U.S. Patent Application Publication No. US 2011/0148261 A1, the entirety of each of which is incorporated herein by reference. It will be appreciated that, in various embodiments, and as illustrated in the above-referenced patents and patent application publications and elsewhere, vertical mounting rails may be supported by the side cross members of the frame, by separate side horizontal rails that are not part of the primary frame structure, or by other means entirely.

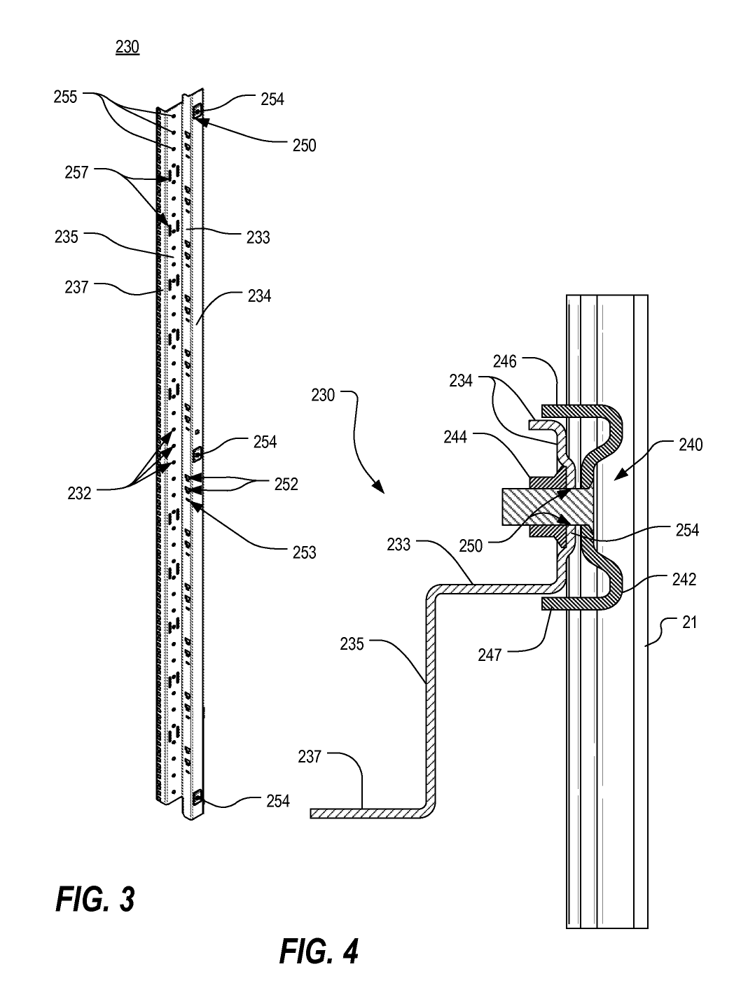

FIG. 3 is an isometric view of one of the vertical mounting rails 230 of FIG. 1, and FIG. 4 is a top cross-sectional view of a portion of the frame structure 12 of FIG. 1, taken along line 4-4, showing the connection of one of the mounting rails 230 to one of the side cross members 21. The mounting rail 230 in FIG. 3 is shown in the same orientation as that of the rightmost mounting rail 230 of FIG. 1. As shown therein, the vertical mounting rail 230 is an elongate structure whose cross-section generally includes a C-shaped portion 234, a first support portion 233 extending from one end of the C-shaped portion 234, a second support portion 235 extending perpendicularly from the first support portion 233, and a third support portion 237 extending perpendicularly from the second support portion 235.

Each vertical mounting rail 230 may be fastened to the cabinet structure 12 using one or more clamps 240. In this regard, the mounting clamp 240 includes a clamping bracket 242 and a clamp nut 244, and the rail 230 includes a plurality of embossed portions 254 for interfacing with the clamp 240. Extending at opposite lateral edges of the clamping bracket 242 are flanges 246,247. The flanges 246,247 of the clamping bracket 242 straddle the C-shaped portion 234 of the vertical mounting rail 230, and the clamp nut 244 may be aligned with the embossed portion 254 of the vertical mounting rail 230, which itself is aligned with a raised central portion of the clamping bracket 242. These features, and a clamp 240 suitable for use in one or more preferred embodiments of the present invention, are described and illustrated in co-pending, commonly-assigned non-provisional patent application Ser. No. 13/229,707, entitled, “RAIL MOUNTING CLAMP FOR ELECTRONIC EQUIPMENT ENCLOSURE.” However, it will be apparent that in at least some embodiments, alternative side cross member structures, connection means, or both may be utilized to connect the vertical mounting rails 230 to the frame structure 12.

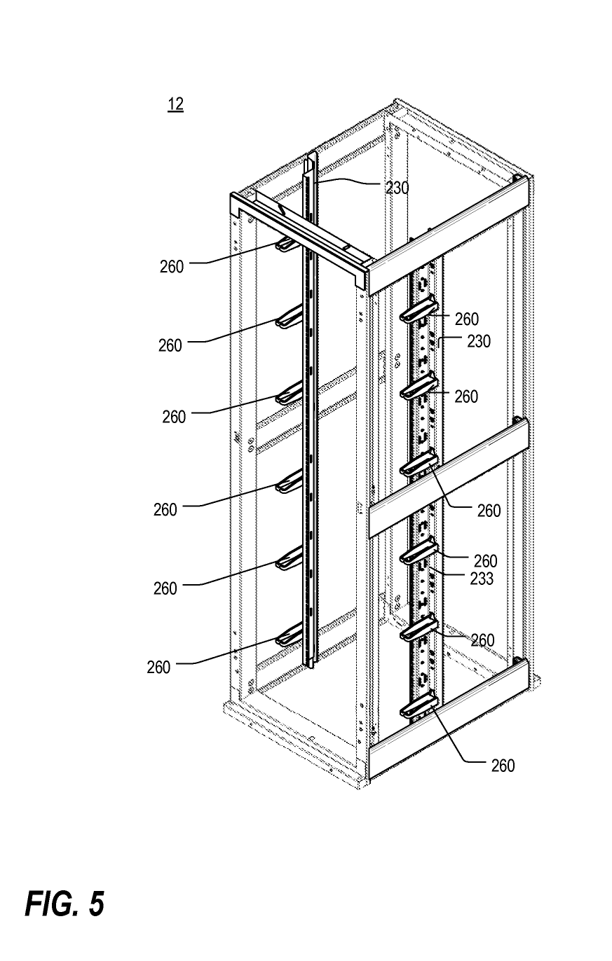

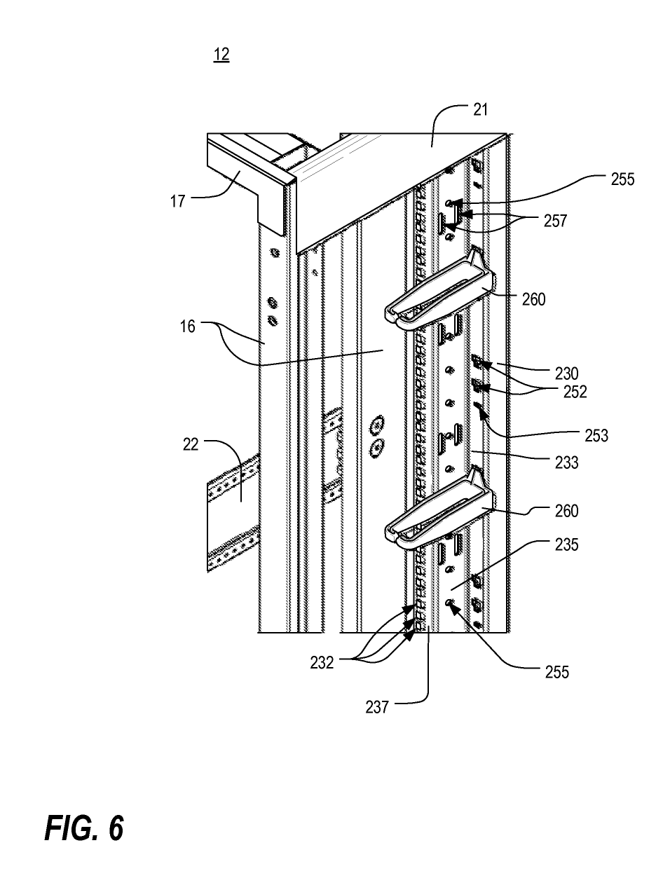

A variety of mounting features is disposed along each of the first, second and third support portions 233,235,237; such features may be used for mounting equipment as well as cable management structures. In this regard, FIG. 5 is an isometric view of the frame structure 12 of FIG. 1, shown with a plurality of D-rings 260 mounted on each vertical mounting rail 230, and FIG. 6 is an enlarged fragmentary isometric view of the top right corner of the frame structure 12 of FIG. 5. With particular reference to FIGS. 3, 5 and 6, the first support portion 233 includes two types of openings 252,253, arranged in sets. In each set are two keyhole apertures 252 disposed above a single horizontal slot 253. The second support portion 235 also includes two types of openings 255,257; circular openings 255 are arranged in a column and evenly-spaced along the length of the rail 230, and vertical slots 257 are arranged in pairs that are likewise evenly-spaced, though at greater spacings, along the rail 230. Finally, the third support portion 237 includes the equipment mounting holes 232 mentioned previously. These holes are preferably square, but may alternatively be round, and are arranged in a conventional, standardized repeating pattern having intervals (on center) of ⅝″-⅝″-½″ totaling a standard rack mounting unit (“RMU”) of 1.75″. The third support portion 237 thus serves as an equipment mounting rail, suitable for use in like manner to conventional equipment mounting rails having conventionally-spaced mounting apertures like those shown and described herein.

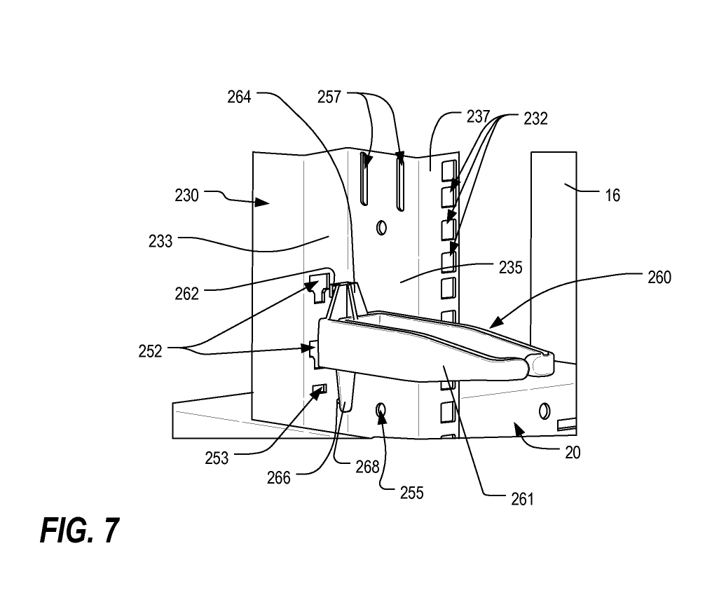

In FIGS. 5 and 6, the cable management structures that are mounted on the vertical mounting rails are D-rings 260, although a wide variety of different cable management structures may be mounted to the vertical mounting rails, as will be explained in further detail below. FIG. 7 is an enlarged fragmentary orthogonal view of one of the D-rings 260 of FIG. 5 shown detached from the vertical mounting rail 230. Each D-ring 260 includes a ring portion 261 and a support portion. The ring portion 261 may be generally similar in construction to, for example, cable rings described and illustrated in commonly-assigned U.S. Pat. No. 6,504,100, entitled “FLEXIBLE INTRA-CABINET CABLE RING WIRE MANAGEMENT SYSTEM,” the entirety of which is incorporated herein by reference. However, in some embodiments, other types of cable rings may be substituted therefor. The support portion includes three elements: a first keyhole boss 262 extending laterally from the back of a tab 264 protruding upward from the back of the ring portion 261, a second keyhole boss (not visible, but similar to the first keyhole boss 262) extending laterally from the back of the ring portion 261, and an alignment boss 266 protruding from the end of a tab 268 extending downward from the back of the ring portion 261. The support portion of the D-ring 260 is adapted to be connected to, and supported by, one set of openings 252,253 in the vertical mounting rail 230 without interfering with the use of the equipment mounting holes 232. In particular, the two keyhole bosses 262 are arranged to interact with the keyhole apertures 252, of the selected set of openings 252,253, in the first support portion 233, and the alignment boss 266 is arranged to interact with the horizontal slot 253 of the same set of openings 252,253. This interaction may perhaps be best discerned from FIGS. 6 and 7.

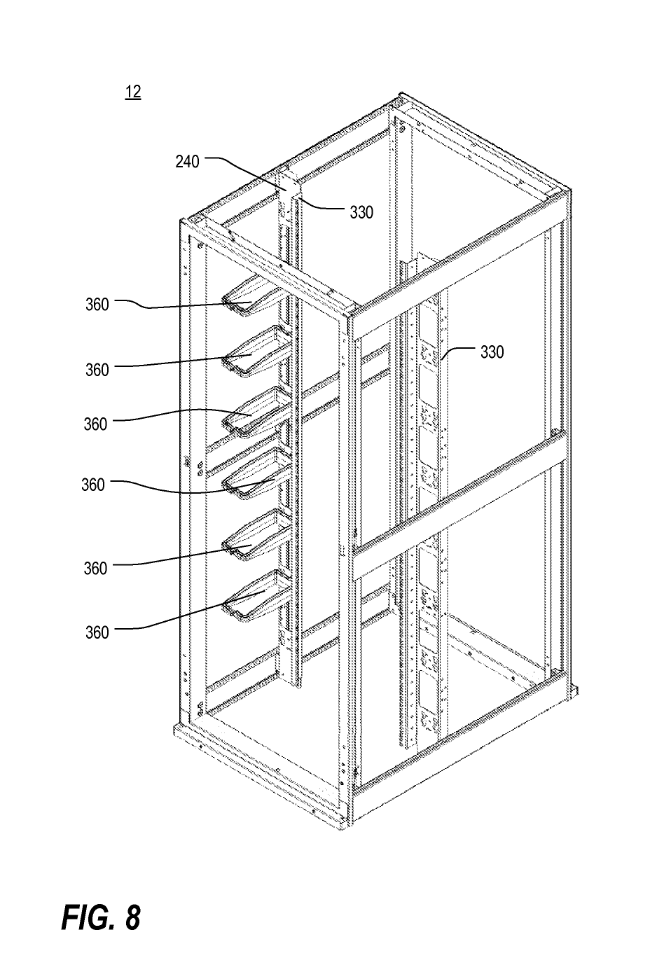

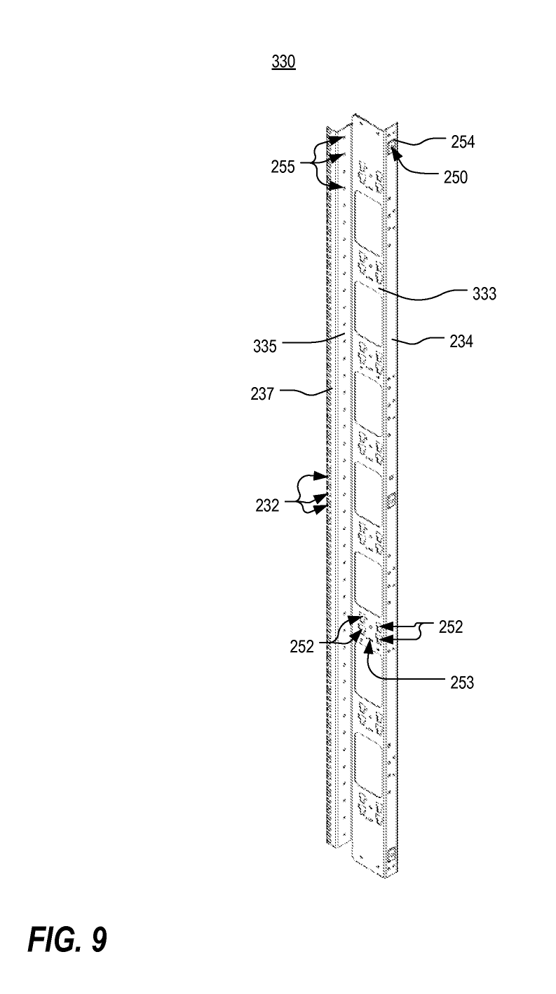

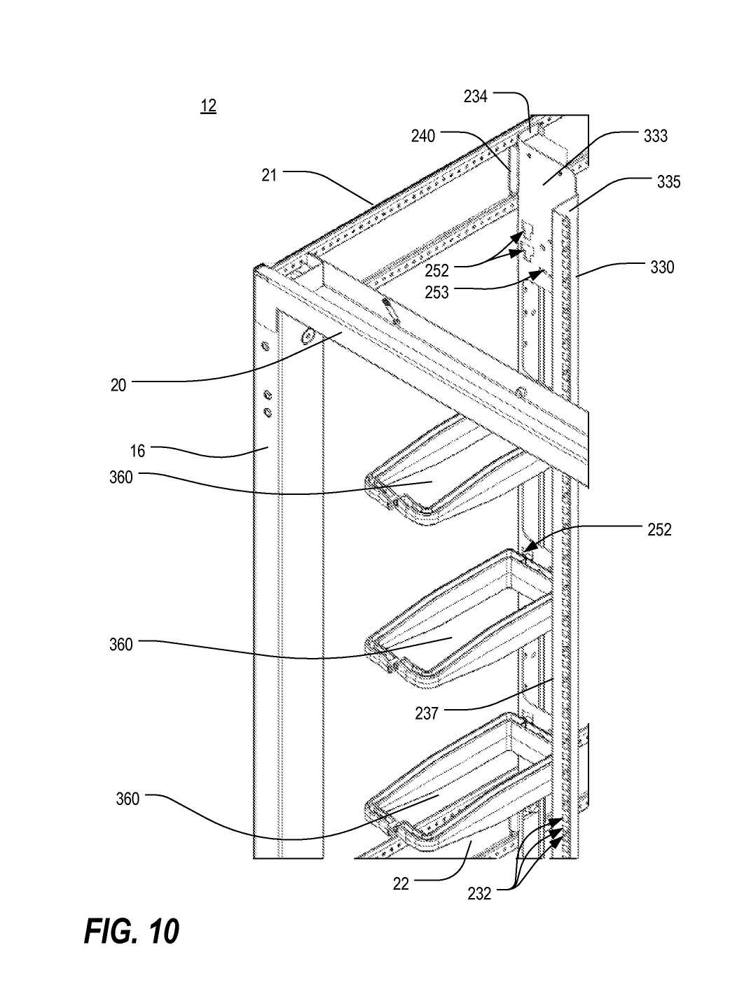

FIG. 8 is an isometric view of a frame structure 12 of similar construction to that of FIG. 1, but of greater depth and width, shown with an alternative type of vertical mounting rail 330 installed thereon, and FIG. 9 is an isometric view of one of the vertical mounting rails 330 of FIG. 8. As will be apparent, the mounting rail 330 in FIG. 9 is shown in the same orientation as that of the rightmost mounting rail 330 of FIG. 1. Still further, FIG. 10 is an enlarged fragmentary isometric view of the top left corner of the frame structure 12 of FIG. 8.

The alternative mounting rail 330 of FIGS. 8-10 shares many similarities with the mounting rail 230 of FIGS. 1 and 3. The alternative vertical mounting rail 330 is an elongate structure whose cross-section generally includes a C-shaped portion 234, a first support portion 333 extending from one end of the C-shaped portion, a second support portion 335 extending perpendicularly from the first support portion 333, and a third support portion 237 extending perpendicularly from the second support portion 335. The rail 330 may be fastened to the cabinet structure 12 using one or more clamps 240 in similar fashion to that of FIG. 3. A variety of mounting features is disposed along each of the first, second and third support portions 333,335,237; such features may be used for mounting equipment as well as cable management structures. The first support portion 333 includes at least two types of openings 252,253, arranged in sets. In each set are two pairs of keyhole apertures 252 disposed above a single horizontal slot 253, which is centered therebetween. The second support portion 335 includes circular openings 255 are arranged in a column and evenly-spaced along the length of the rail 330. The third support portion 237 includes the standardized equipment mounting holes 232 mentioned previously. In addition to other openings, one or more of the support portions 333,335,237 may be adapted to facilitate routing of cables from one side of the frame structure 12 to the other. Options and features for accommodating cable pass-through at a vertical mounting rail may be disclosed, for example, in co-pending, commonly-assigned non-provisional patent application Ser. No. 13/229,706, entitled, “RAIL SEAL FOR ELECTRONIC EQUIPMENT ENCLOSURE” (the “'706 Application”).

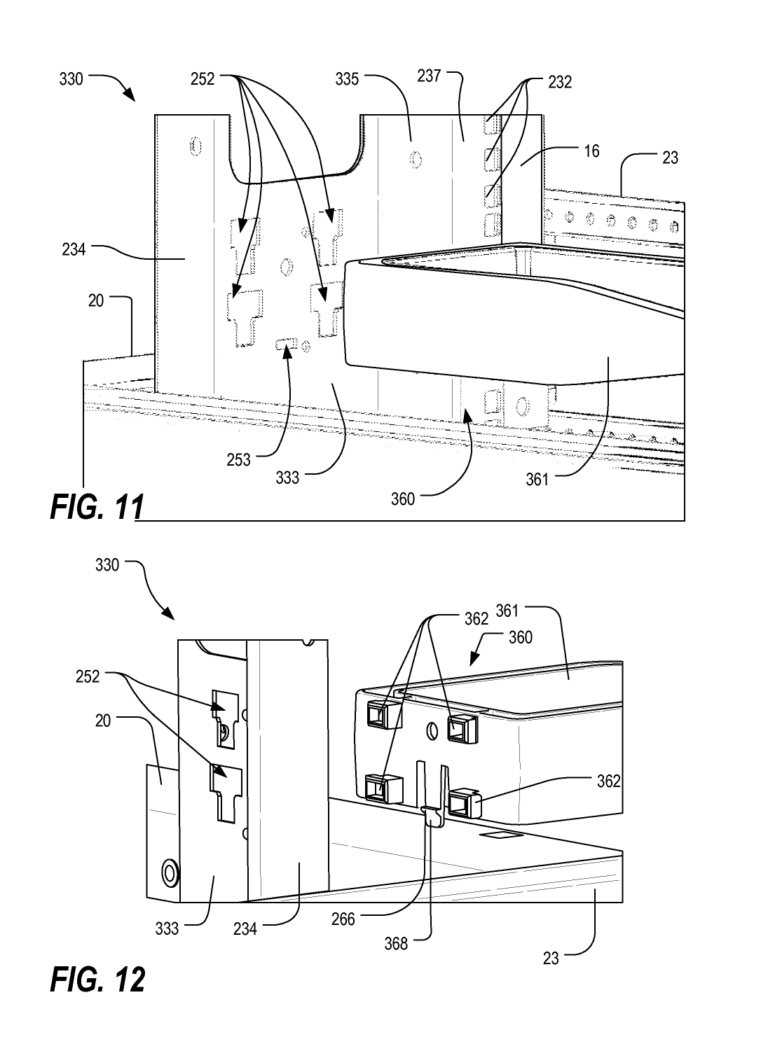

In FIGS. 8 and 10, the cable management structures that are mounted on the vertical mounting rails are D-rings 360, although a wide variety of different cable management structures may be mounted to the vertical mounting rails, as will be explained in further detail below. FIGS. 11 and 12 are enlarged fragmentary orthogonal view of the left side and rear of one of the D-rings 360 of FIG. 8 shown detached from the vertical mounting rail 330. Each D-ring 360 includes a ring portion 361 and a support portion. The ring portion 361 may be generally similar in construction to the ring portion of the D-rings of FIGS. 5-7 and variations thereof. The support portion includes five elements: four keyhole bosses 362 extending laterally from the back of the ring portion 361, and an alignment boss 266 protruding from the end of a tab 368 extending downward from a central area of the back of the ring portion 361. The support portion of the D-ring 360 is adapted to be connected to, and supported by, one set of openings 252,253 in the vertical mounting rail 330 without interfering with the use of the equipment mounting holes 232. In particular, the four keyhole bosses 362 are arranged to interact with the keyhole apertures 252, of the selected set of openings 252,253, in the first support portion 333, and the alignment boss 266 is arranged to interact with the horizontal slot 253 of the same set of openings 252,253. This interaction may perhaps be best discerned from FIGS. 10-12 but is somewhat similar to that of the D-rings 260 shown in FIGS. 6 and 7.

Notably, the D-rings 260,360 described and illustrated herein may be connected to, or mounted on, the vertical mounting rails 230,330 without the use of tools. In particular, the D-rings 260,360 may be mounted by inserting the keyhole bosses 262,362 into the upper (wider) portion of respective keyhole apertures 252 and lowering them until they are seated in the lower (narrower) portion thereof, at which point the alignment boss 266 snaps into place in the horizontal slot 253. In at least some embodiments, keyhole apertures 252 may be of varying sizes. For example, in at least some embodiments, an upper keyhole aperture may be smaller than a lower keyhole aperture.

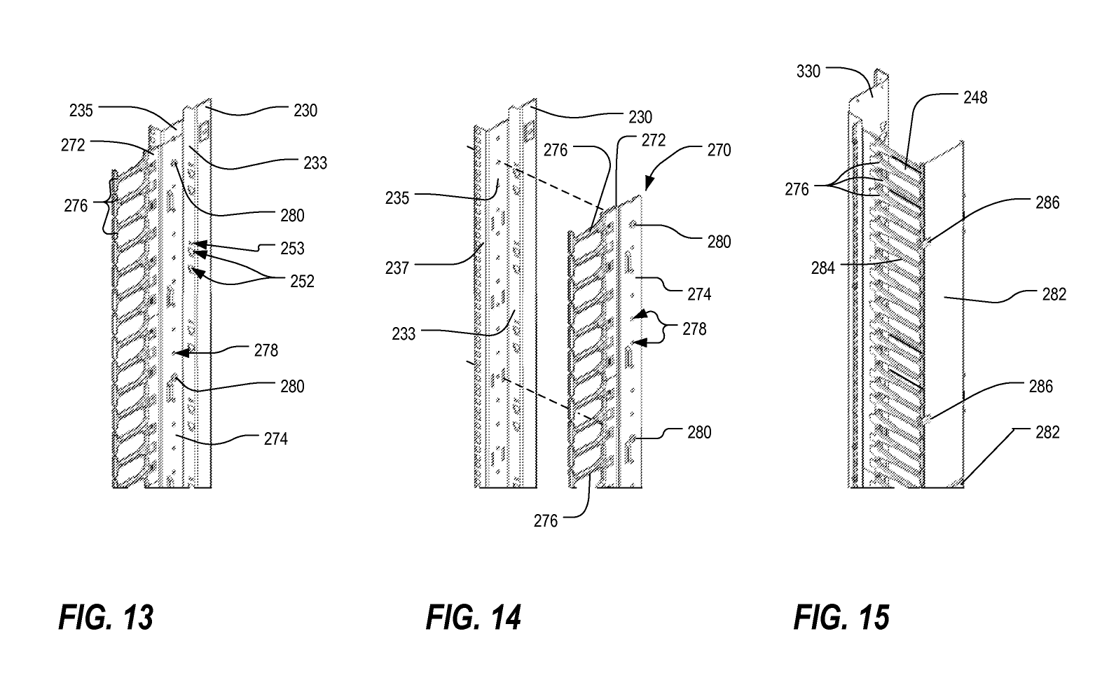

FIG. 13 is a fragmentary isometric view of a top portion of the vertical mounting rail 230 of FIG. 3, shown with a plurality of cable management structures in the form of multi-fingered cable guides 270 mounted thereon, and FIG. 14 is an exploded fragmentary isometric view of the vertical mounting rail 230 and cable guides 270 of FIG. 13. As shown therein, each cable guide includes a cable ring portion 272, which includes a plurality of T-shaped fingers 276 forming cable rings therebetween, and a base portion 274, which is generally planar and includes a plurality of circular openings 278 arranged in a column and distributed along the length thereof at a spacing that corresponds to that of the openings 255 in the second support portion 235 of the mounting rail 230. In this regard, cable management structures suitable for use as the cable ring portions 272 of the present invention are shown and described in commonly-assigned U.S. Pat. No. 7,119,282, entitled “VERTICAL CABLE MANAGEMENT RACK,” the entirety of which is incorporated herein by reference. Like the structures described therein, the T-shaped fingers 276 are preferably arranged at 1 RMU spacings. The multi-fingered cable guides 270 may be attached to, and flush against, the second support portion 235 of the mounting rail 230 using fasteners 280. In this arrangement, unrestricted access to the sets of openings 252,253 in the first support portion 233 continues to be available, thereby permitting D-rings 260 or other cable management structures to be mounted thereto if desired. Furthermore, the cable rings formed by the T-shaped fingers 276 are conveniently located alongside equipment mounted to the equipment mounting rails (third support portions) 233. Still further, because the T-shaped fingers 276 and the cable rings formed thereby are arranged at 1 RMU spacings, the cable rings are aligned with conventional, standardized rack mounting locations defined by the equipment mounting holes 232.

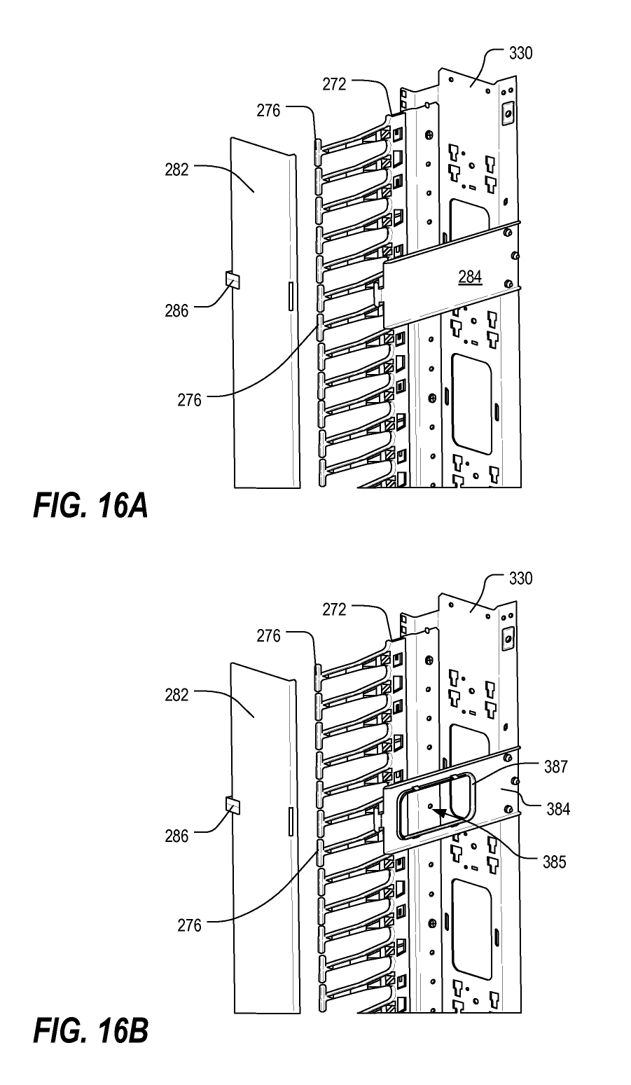

FIG. 15 is a fragmentary isometric view of a top portion of the vertical mounting rail 330 of FIG. 9, taken from the left side, shown with a plurality of cable management structures in the form of multi-fingered cable guides 270, doors 282 and door supports 284 mounted thereon, and FIG. 16A is a partially exploded fragmentary isometric view, taken from the right side, of the arrangement of FIG. 15. The cable guides 270 are similar to those of FIGS. 13 and 14 and are installed in like manner to the second support portions 335 of a mounting rail 330. The doors 282 may be supported along one side with hinges 286 supported between adjacent ends of the T-shaped fingers 276 and on the other side by the door supports 284. As shown in FIG. 16A, each door support 284 is itself supported by the C-shaped portion 234 using fasteners 280. FIG. 16B is a partially exploded fragmentary isometric view, taken from the right side, of an alternative embodiment of the arrangement of FIG. 16A. As shown in FIG. 16B, a door support 384 may itself include an aperture 385 to permit cables to pass therethrough. Edges 387 of the aperture 385 can be rounded so as to prevent unnecessary friction against cables positioned to pass through the aperture 385. Further details regarding the arrangement of FIGS. 15, 16A and 16B can be found in the '706 Application.

In certain contemplated embodiments (not illustrated), cable management structures may be separately anchored to the vertical mounting rail 230,330 or frame structure 12 after being fastened to the vertical mounting rail 230,330. Such anchoring may be facilitated with a separate fastener. In at least some other embodiments, such anchoring is not required for structural stability.

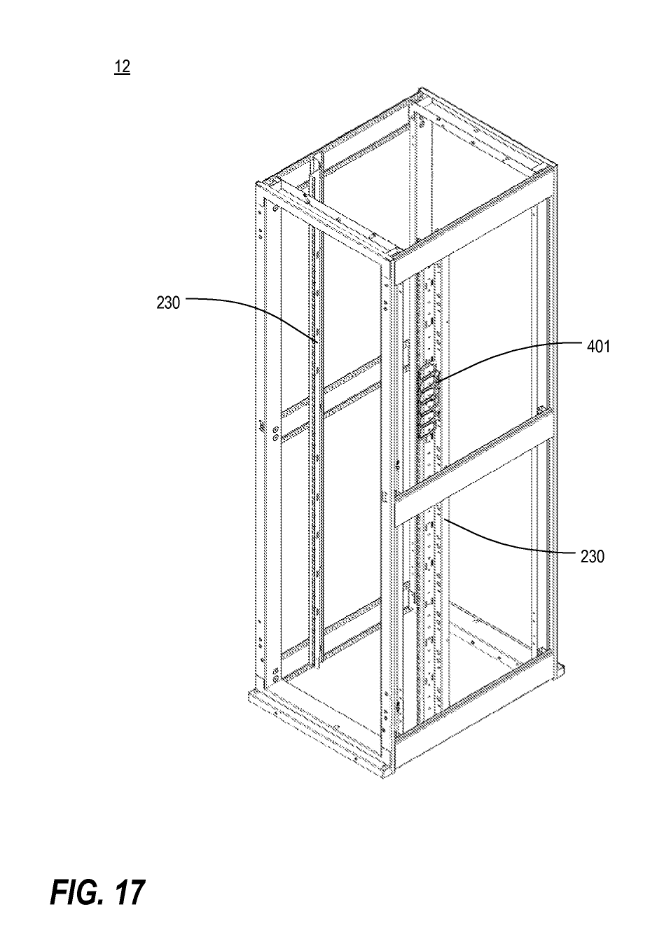

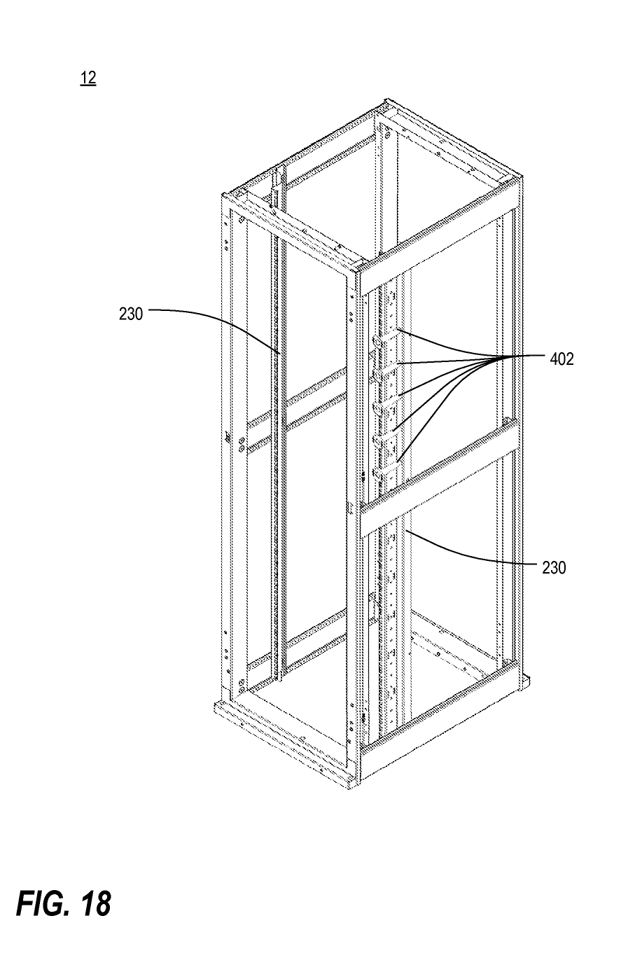

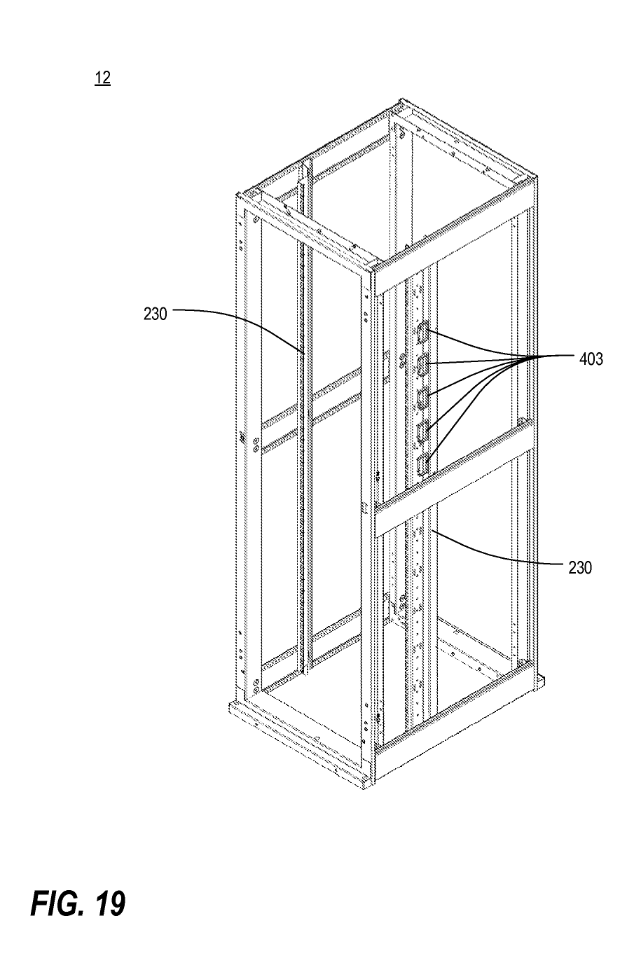

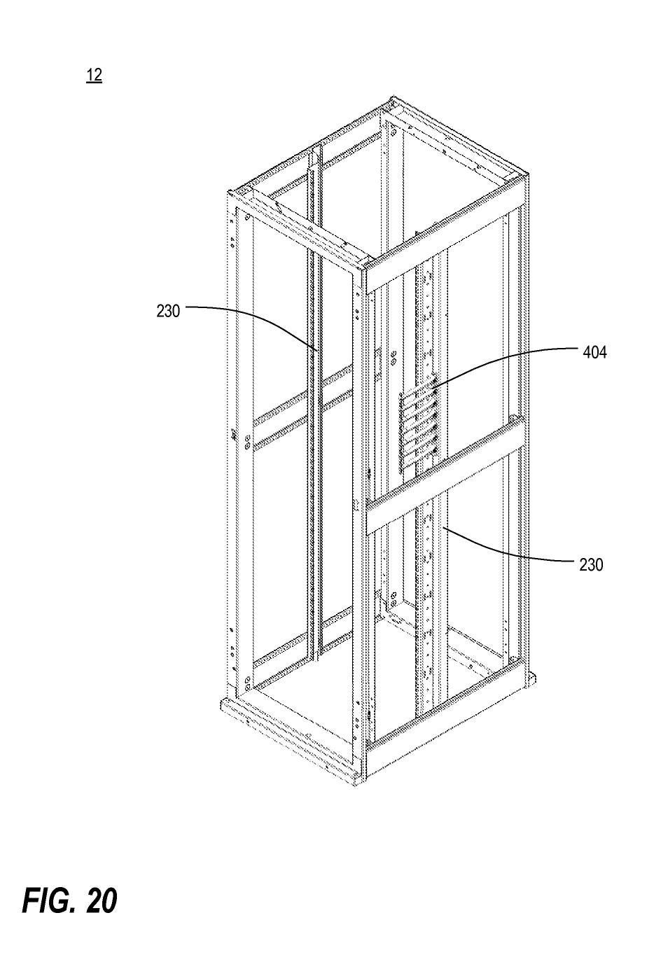

FIGS. 17-20 illustrate the frame structure 12 of FIG. 1 with various other cable management structures mounted to the vertical mounting rails 230. FIG. 17 is an isometric view of the frame structure 12 of FIG. 1, shown with a T-channel cable manager array 401 mounted on one of the vertical mounting rails 230. FIG. 18 is an isometric view of the frame structure 12 of FIG. 1, shown with a plurality of cable manager spools 402 mounted on one of the vertical mounting rails 230. FIG. 19 is an isometric view of the frame structure 12 of FIG. 1, shown with a plurality of vertical C-channel cable managers 403 mounted on one of the vertical mounting rails 230. FIG. 20 is an isometric view of the frame structure 12 of FIG. 1, shown with a multi-finger cable manager array 404 mounted on one of the vertical mounting rails 230.

Based on the foregoing information, it will be readily understood by those persons skilled in the art that the present invention is susceptible of broad utility and application. Many embodiments and adaptations of the present invention other than those specifically described herein, as well as many variations, modifications, and equivalent arrangements, will be apparent from or reasonably suggested by the present invention and the foregoing descriptions thereof, without departing from the substance or scope of the present invention.

Accordingly, while the present invention has been described herein in detail in relation to one or more preferred embodiments, it is to be understood that this disclosure is only illustrative and exemplary of the present invention and is made merely for the purpose of providing a full and enabling disclosure of the invention. The foregoing disclosure is not intended to be construed to limit the present invention or otherwise exclude any such other embodiments, adaptations, variations, modifications or equivalent arrangements; the present invention being limited only by the claims appended hereto and the equivalents thereof.

1. An electronic equipment enclosure comprising:
a) a frame structure that includes side cross members between front and rear frames;
(b) a vertical mounting rail fastened to the frame structure, the vertical mounting rail including a fastening portion, for interfacing with the frame structure, and at least one support portion including an aperture therein; and
(c) a first cable management structure having a boss adapted to be maneuvered into the aperture and seated therein so as to fasten, without a separate fastener, the first cable management structure to the at least one support portion.

2. The electronic equipment enclosure of claim 1, wherein the first cable management structure is adapted to be snap-fit to the at least one support portion.

3. The electronic equipment enclosure of claim 1, wherein the first cable management structure is adapted to be fastened to the at least one support portion without the aid of tools.

4. The electronic equipment enclosure of claim 1, wherein a second cable management structure having a boss is adapted to be maneuvered into another aperture of the at least one support portion, and seated therein, so as to fasten, without a separate fastener, the second cable management structure to the at least one support portion.

5. The electronic equipment enclosure of claim 4, wherein the second cable management structure is of the same type as that of the first cable management structure.

6. The electronic equipment enclosure of claim 4, wherein the second cable management structure is of a different type than that of the first cable management structure.

7. The electronic equipment enclosure of claim 1, wherein the aperture of the at least one support portion has a keyhole shape.

8. The electronic equipment enclosure of claim 1, wherein the at least one support portion is an equipment mounting rail.

9. The electronic equipment enclosure of claim 1, wherein the at least one support portion includes first, second and third support portions located successively adjacent one another.

10. The electronic equipment enclosure of claim 9, wherein the first, second and third support portions are arranged at right angles relative to one another.

11. The electronic equipment enclosure of claim 9, wherein the second support portion has a width greater than that of the first or third support portions.

12. The electronic equipment enclosure of claim 9, wherein a second cable management structure is fastened to the same support portion as that of the first cable management structure.

13. The electronic equipment enclosure of claim 9, wherein a second cable management structure is fastened to a different support portion than that of the first cable management structure.

14. The electronic equipment enclosure of claim 1, wherein the first cable management structure is a D-ring.

15. The electronic equipment enclosure of claim 1, wherein the first cable management structure is a multi-fingered cable guide.

16. The electronic equipment enclosure of claim 1, wherein the first cable management structure is a T-channel cable manager array.

17. The electronic equipment enclosure of claim 1, wherein the first cable management structure is a cable manager spool.

18. The electronic equipment enclosure of claim 1, wherein the first cable management structure is a vertical C-channel cable manager.

19.-35. (canceled)
